(19) United States
(12) Patent Application Publication
(10) Pub. No.: US 2010/0148996 A1
(43) Pub. Date: Jun. 17, 2010

(54) Light guide structure for a keyboard

(75) Inventor: Chien-Lung Wang, Taipei (TW)

Correspondence Address: BACON & THOMAS, PLLC, 625 SLATERS LANE, FOURTH FLOOR, ALEXANDRIA, VA, 22314-1176, US

(73) Assignee: KINPO ELECTRONICS, INC., Taipei (TW)

(21) Appl. No.: 12/379,958

(22) Filed: Mar. 5, 2009

(30) Foreign Application Priority Data
Dec. 16, 2008 (TW) 097149054

(51) Int. Cl. H03M 11/00

(52) U.S. Cl. 341/22

(57) ABSTRACT

A light guide structure for a keyboard. The light guide structure includes a transparent rubber sheet. Multiple resilient support sections are formed on the rubber sheet in alignment with press keys of the keyboard respectively. Multiple diffusive reflection units are disposed on a surface of the rubber sheet and circumferences of the resilient support sections. The diffusive reflection units are boss sections protruding from the surface of the rubber sheet or recessed sections formed on the surface of the rubber sheet. Each diffusive reflection unit has a surface coated with a light reflection layer for reflecting light. When the light is reflected by external components back to the surface of the rubber sheet, the light reflection layers of the diffusive reflection units that are boss sections or recessed sections will again effectively reflect the light to enhance backlight brightness of the press keys and peripheries thereof.

### BACKGROUND OF THE INVENTION

The present invention is related to a light guide structure for a keyboard, and more particularly to a rubber sheet light guide structure, which is able to enhance backlight brightness of press keys of the keyboard and promote reuse efficiency of light.

FIG. 1 shows a backlight structure applied to a press key of an electronic product. The backlight structure includes a nontransparent press key 51, a light guide element 5 and a light-emitting element 52. The light-emitting element 52 is arranged on a backside of the press key 51. The light emitted from the light-emitting element 52 is guided by the light guide element 5 around the press key 51 and projected to a front side of the press key 51. By means of the arrangement of the light guide element 5 and the light-emitting element 52, the light can be uniformly distributed over a periphery of the press key 51 without local bright spot.

According to the above arrangement, the light emitted from the light-emitting element 52 is all guided to the periphery of the press key 51 rather than the interior thereof. The structure that is nearby to the press key 51 for supporting and electrically contacting the press key 51 is quite complicated. Such structure will obviously obstruct the path of the light guided by the light guide element 5. Accordingly, the center of the press key 51 can be hardly sufficiently illuminated and a shadow will exist at the center of the press key 51. Moreover, a large number of light-emitting elements 52 are needed in such structure. This directly leads to increment of manufacturing cost. This also increases complicatedness in circuit design and results in higher power consumption. Apparently, such structure is not economic.

FIG. 2 shows another conventional structure including a press key 6 and a bridgeboard 62 transversely disposed under the press key 6. A bottom board 61 is further parallelly disposed under the bridgeboard 62 and spaced therefrom. The bottom board 61 has a surface in contact with a circuit board 63. A light travel space 661 is defined between the bridgeboard 62 and the circuit board 63 (bottom board 61). A light source 66 is positioned beside the light travel space 661. At least one light guide section 65 is inlaid in the bridgeboard 62 in a position corresponding to the press key 6. A bottom end of the light guide section 65 downward extends into the light travel space 661. In use, the light emitted from the light source 66 goes into the light travel space 661 and is guided/refracted upward by the bottom end of the light guide section 65 to the press key 6 as a backlight for the press key 6.

FIG. 3 shows still another conventional backlight module applied to a keyboard structure. The backlight module includes a substrate 71, a light guide plate (LGP) 7 attached to an upper face of the substrate 71 and a diffusion layer 73 attached to an upper face of the LGP 7 for scattering the light passing through the LGP 7. The diffusion layer 73 is formed with multiple through holes 731. A keyboard matrix circuit layer 74 made of light transmission material is attached to an upper face of the diffusion layer 73. A film 75 made of light transmission material is laid on an upper face of the keyboard matrix circuit layer 74. Multiple rubber sheet-made bell-shaped members 751 are arranged on the film 75 in alignment with the through holes 731 respectively. A cover member 76 is mounted on an upper face of the film 75. Multiple press keys 77 are arranged on the cover member 76 in alignment with the through holes 731 respectively. At least one light-emitting diode (LED) 72 is disposed on the substrate 71 beside the LGP 7. The light emitted from the LED 72 is first transversely transmitted through the LGP 7 and then upward guided to the diffusion layer 73. The light goes through the through holes 731 and the keyboard matrix circuit layer 74 as well as the bell-shaped members 751 to provide a backlight effect for the press key 77 and an area around the press key 77.

In the structures of FIGS. 2 and 3, the light is upward guided by the light guide elements and uniformly scattered. However, in practice, there are many components (such as the case and the press key) are arranged around the light guide elements. These components all will reflect light. Therefore, the light coming from the light guide elements or the light source will be again and again reflected to the periphery of the press key and lost. The randomly scattered light is not fully utilized so that the illumination provided by the backlight module can be hardly enhanced.

FIGS. 4 and 4A show another common rubber membrane 8, which is attached to an upper face of a circuit board. At least one naturally raised (bell-shaped) resilient support section 81 is disposed on the rubber membrane 8 corresponding to each electric contact point of the circuit board. A top side of the resilient support section 81 is formed with an abutment unit 82. A conductive carbon paste layer 83 is painted under a bottom face of the abutment unit 82. The light guide plate generally is attached to an upper face of the rubber membrane 8. The press key 4 is disposed above the light guide plate to abut against a top face of the abutment unit 82 of the rubber membrane 8.

In the above structure, the light coming from the light guide plate can provide backlight illumination for the periphery of the press key and the transparent sections of the case. Moreover, in order to enhance the backlight illumination, the press key is often made of transparent material, whereby the light can penetrate through the press key without being obstructed. However, in practice, the carbon paste layer 83 is black so that the light cannot penetrate through the carbon paste layer 83. Moreover, even if the light is partially reflected downward from the inner face of the case or the lower face of the press key, the light still cannot pass through the carbon paste layer 83 to be reflected upward. Therefore, a shadow is often produced at the center of the press key due to insufficient backlight.

### SUMMARY OF THE INVENTION

It is therefore a primary object of the present invention to provide alight guide structure for a keyboard, which is able to enhance uniform backlight illumination of the press keys and peripheries thereof and avoid shadow caused by insufficient backlight brightness.

It is a further object of the present invention to provide the above light guide structure for the keyboard, which is able to promote utility efficiency of light and lower power consumption.

According to the above objects, the light guide structure for the keyboard of the present invention includes a transparent rubber sheet arranged between the press keys of the keyboard and a circuit board. At least one resilient support section is formed on the rubber sheet in alignment with a press key of the keyboard. A top side of the resilient support section is positioned right under a bottom face of the press key or in contact with the bottom face of the press key. Multiple diffusive reflection units are formed on a surface of the rubber sheet and distributed over a circumference of the resilient support section. Each diffusive reflection unit has a surface coated with a light reflection layer.

The diffusive reflection units are also distributed over portions of the surface of the rubber sheet that are other than the resilient support section.

The resilient support section is transparent and the diffusive reflection units are distributed over inner circumference of the resilient support section.

At least one light reflection layer is disposed under a bottom face of an abutment unit of the top side of the resilient support section. At least one carbon paste layer is disposed under a bottom face of the light reflection layer. Accordingly, the light reflection layer is able to reflect light toward the press key, which light comes from a light guide plate or from other light sources. Therefore, the light guide structure is able to enhance reuse efficiency of the light and avoid the shadow caused by the carbon paste layer.

The present invention can be best understood through the following description and accompanying drawings wherein:

### BRIEF DESCRIPTION OF THE DRAWINGS

FIG. 1 is a sectional view of a conventional backlight structure for a press key;

FIG. 2 is a sectional view of another conventional backlight structure for a press key;

FIG. 3 is a sectional view of still another conventional backlight structure for a press key;

FIG. 4 is a perspective view of a rubber membrane with carbon paste sections;

FIG. 4A is an enlarged view of circled area 4A of FIG. 4;

FIG. 5 is a perspective exploded view of a first embodiment of the present invention;

FIG. 5A is an enlarged view of circled area 5A of FIG. 5;

FIG. 6 is a sectional assembled view of the first embodiment of the present invention;

FIG. 7 is a sectional assembled view according to FIG. 6, showing the paths of scattered light;

FIG. 8 is a sectional assembled view of a second embodiment of the present invention, showing the paths of scattered light;

FIG. 9 is a sectional assembled view of a third embodiment of the present invention;

FIG. 10 is a sectional assembled view according to FIG. 9, showing the paths of scattered light;

FIG. 11 is a sectional assembled view of a fourth embodiment of the present invention, showing the paths of scattered light;

FIG. 12 is a perspective view of the rubber sheet of a fifth embodiment of the present invention;

FIG. 12A is an enlarged view of circled area 12A of FIG. 12; and

FIG. 13 is a sectional assembled view of the fifth embodiment of the present invention, showing the paths of scattered light.

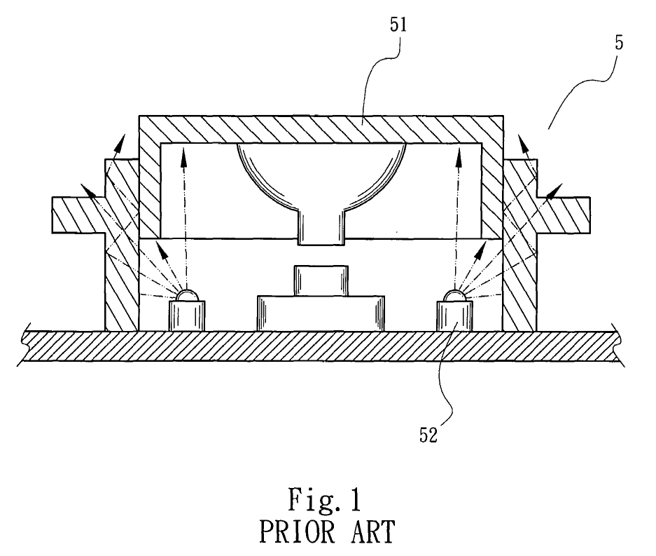

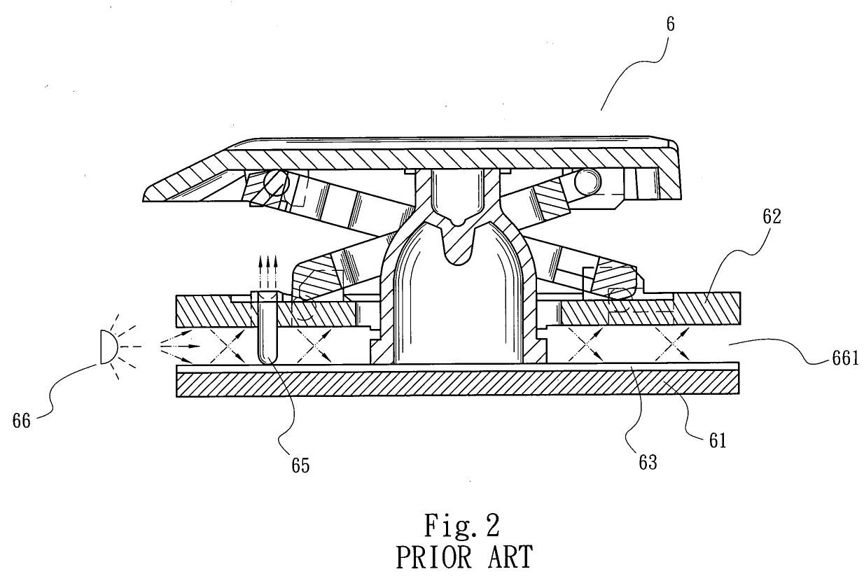

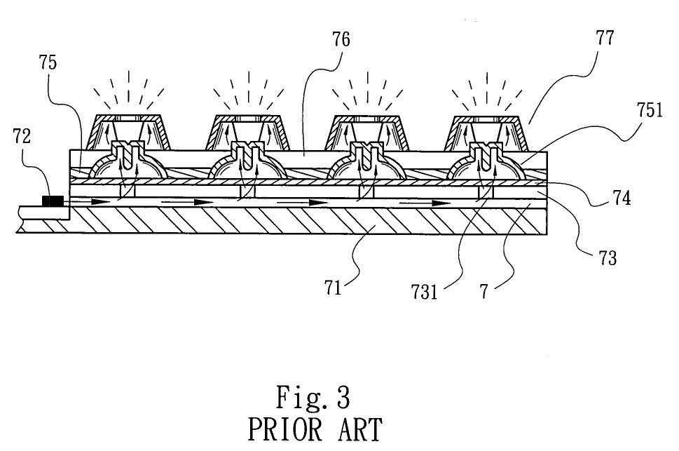

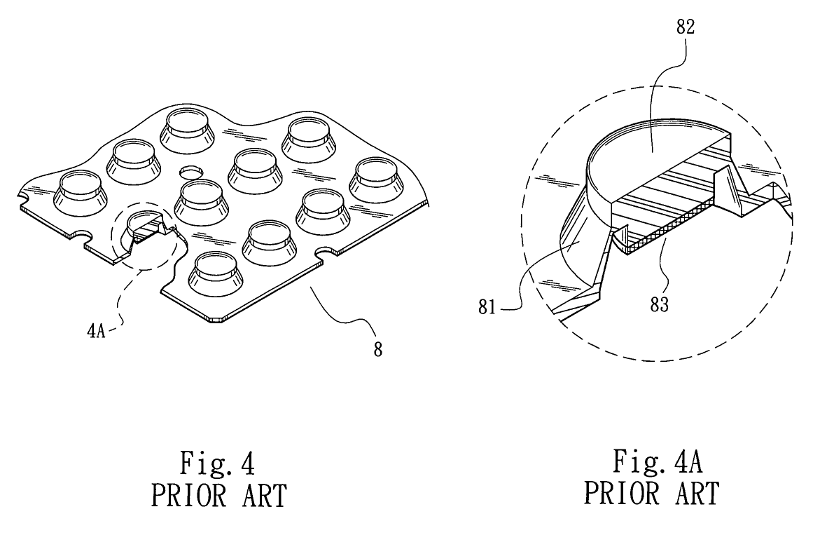

### DETAILED DESCRIPTION OF THE PREFERRED EMBODIMENTS

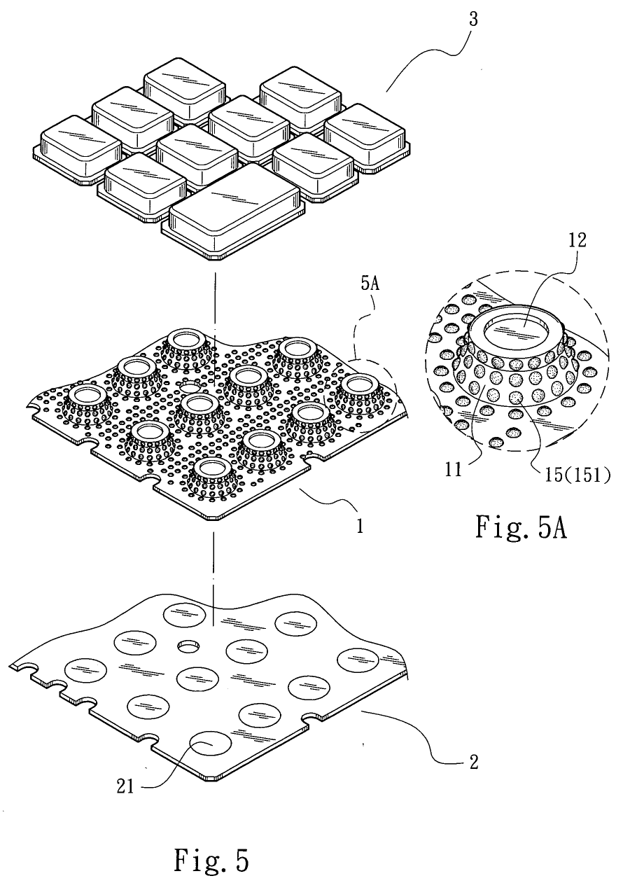

Please refer to FIGS. 5 to 7. According to a first embodiment of the present invention, at least one bell-shaped raised resilient support section 11 is formed on a rubber sheet 1 in alignment with a press key 3. An abutment unit 12 is disposed on a top side of the resilient support section 11. A top face of the abutment unit 12 is positioned right under a bottom face of the press key 3 or in contact with the bottom face of the press key 3. An electric contact section 13 (such as a carbon paste contact) is disposed under a bottom face of the abutment unit 12. At least one diffusive reflection unit 15 is disposed on a surface of the rubber sheet 1 and at least a part of outer circumference of the resilient support section 11. In this embodiment, the diffusive reflection unit 15 is a boss section, a convex section or a dome section protruding from the surface of the rubber sheet 1. The diffusive reflection unit 15 has a surface coated with a light reflection layer 151 for reflecting light. The light reflection layer 151 can be a layer of white paint, light-colored paint or any other light reflection paint.

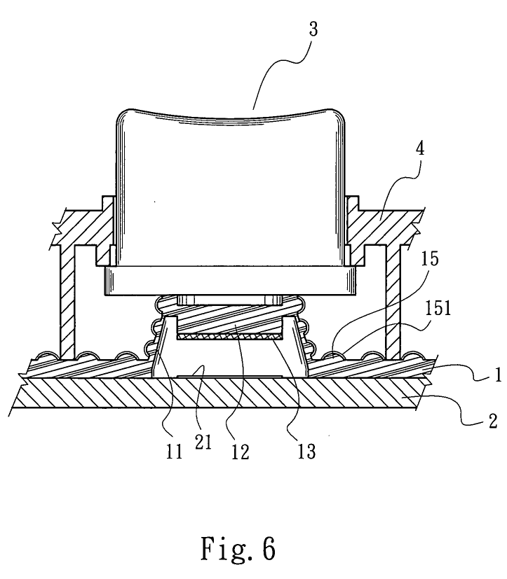

In practice, the rubber sheet 1 can be combined with a circuit board 2 to form a substrate. The circuit board 2 is positioned under the rubber sheet 1. At least one electric contact point 21 is disposed on the circuit board 2 in alignment with the electric contact section 13. When the press key 3 is pressed down, the resilient support section 11 is resiliently deformed, whereby the electric contact section 13 can electrically contact the electric contact point 21 of the circuit board 2. When the press key 3 is released from the pressing force, the resilient support section 11 resiliently restores to its original state so that the electric contact section 13 is restored to its home position. A case 4 can be fitted around the press key 3 to cover those portions of the upper face of the rubber sheet 1 that are not positioned under the press key 3 (as shown in FIGS. 5 and 6).

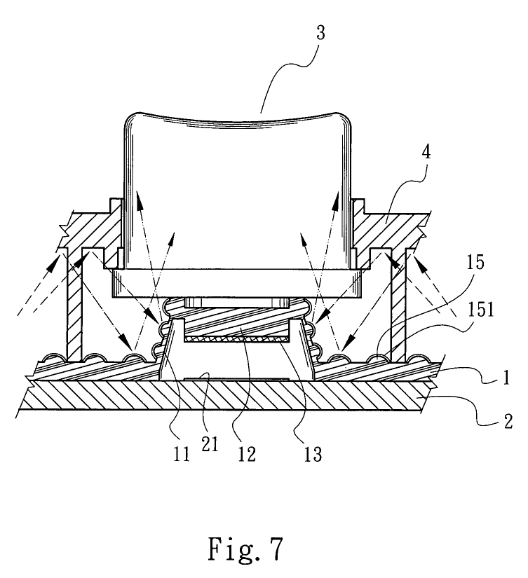

In this embodiment, a light source such as a light-emitting diode (LED), a cold cathode fluorescent lamp or any other light-emitter is used to emit light. The light emitted from the light source is reflected by the inner face of the case 4 or the lower face of the press key 3. Preferably, this embodiment has multiple diffusive reflection units 15, which are boss sections, convex sections or dome sections. The diffusive reflection units 15 are distributed over the outer circumferences of the resilient support sections 11 and/or the upper face of the rubber sheet 1. The light reflection layers 151 coated on the surfaces of the diffusive reflection units 15 have excellent light reflection performance. Therefore, the light reflected downward can be again reflected upward and uniformly scattered over the press key 3 and the peripheral portions thereof (as shown in FIG. 7). Therefore, the backlight brightness of the press key 3 and the periphery thereof can be enhanced to avoid shadow.

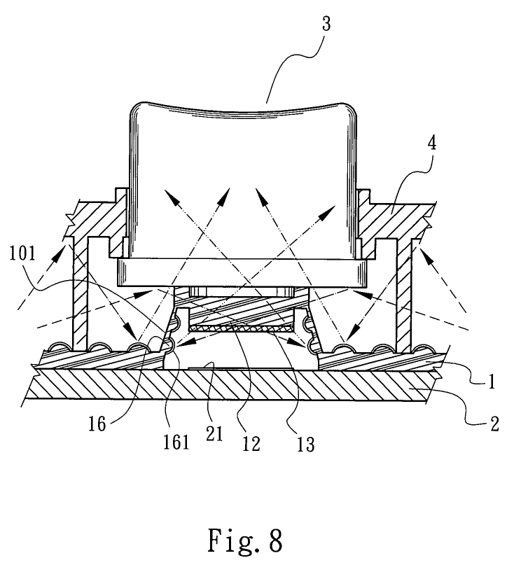

FIG. 8 shows a second embodiment of the present invention, in which the rubber sheet 1a has at least one abutment unit 12 and at least one electric contact section 13 identical to those of the rubber sheet 1 of the first embodiment. The difference between the two embodiments is that the rubber sheet 1a has at least one resilient support section 101 made of transparent material. The diffusive reflection units 16 are boss sections, convex sections or dome sections. The diffusive reflection units 16 are distributed over inner circumferences of the resilient support sections 101 and the upper face of the rubber sheet 1a. Each diffusive reflection unit 16 has a surface coated with a light reflection layer 161. The rubber sheet 1a is connected with the other components in the same manner as in the first embodiment so as to uniformly scatter the light.

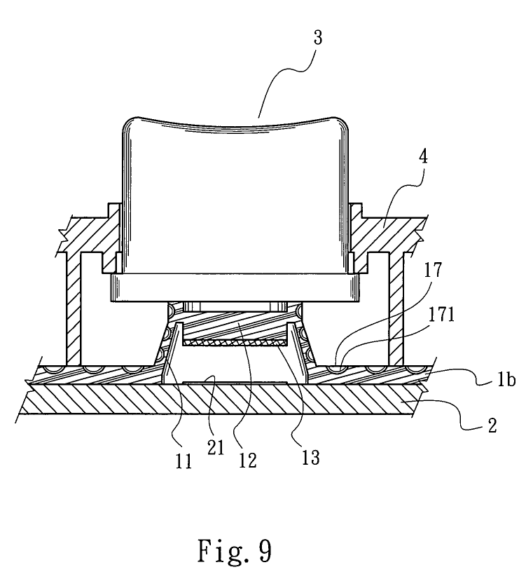

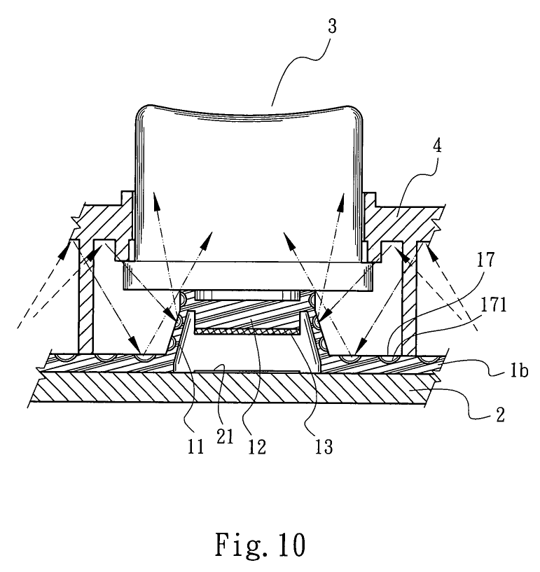

FIGS. 9 and 10 show a third embodiment of the present invention, in which the rubber sheet 1b has at least one resilient support section 11, at least one abutment unit 12 and at least one electric contact section 13 identical to those of the rubber sheet 1 of the first embodiment. The difference between the first and third embodiments is that the diffusive reflection units 17 are recessed sections, concave sections or semispherical dented sections. The diffusive reflection units 17 are uniformly distributed over the upper face of the rubber sheet 1b and the outer circumferences of the resilient support sections 11. Each diffusive reflection unit 17 has a surface coated with a light reflection layer 171 for reflecting light. The light reflection layer 171 can be a layer of light reflection paint.

In practice, the rubber sheet 1b is connected with the other components in the same manner as in the first embodiment. The light emitted from the light source is reflected by the inner face of the case 4 or the lower face of the press key 3. As aforesaid, the diffusive reflection units 17, which are recessed sections, concave sections or semispherical dented sections, are distributed over the outer circumferences of the resilient support sections 11 and the upper face of the rubber sheet 1b. The light reflection layers 171 coated on the surfaces of the diffusive reflection units 17 have excellent light reflection performance. Therefore, the light reflected downward can be again reflected upward by the light reflection layers 171 and uniformly scattered over the press key 3 and the peripheral portions thereof (as shown in FIG. 9). Therefore, the backlight brightness of the press key 3 and the periphery thereof can be enhanced.

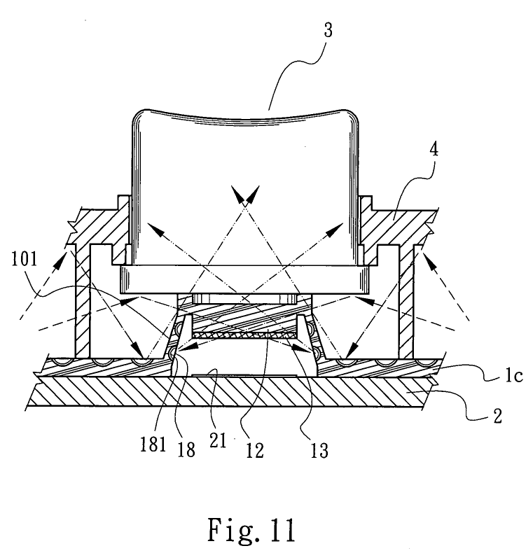

FIG. 11 shows a fourth embodiment of the present invention, in which the rubber sheet 1c has at least one abutment unit 12, at least one electric contact section 13 and at least one transparent resilient support section 101 identical to those of the rubber sheet 1a of the second embodiment. The difference between the fourth and second embodiments is that the diffusive reflection units 18 are recessed sections, concave sections or semispherical dented sections. The diffusive reflection units 18 are distributed over the upper face of the rubber sheet 1c and the inner circumferences of the resilient support sections 101. Each diffusive reflection unit 18 has a surface coated with a light reflection layer 181. The rubber sheet 1c is connected with the other components in the same manner as in the second embodiment so as to uniformly scatter the light.

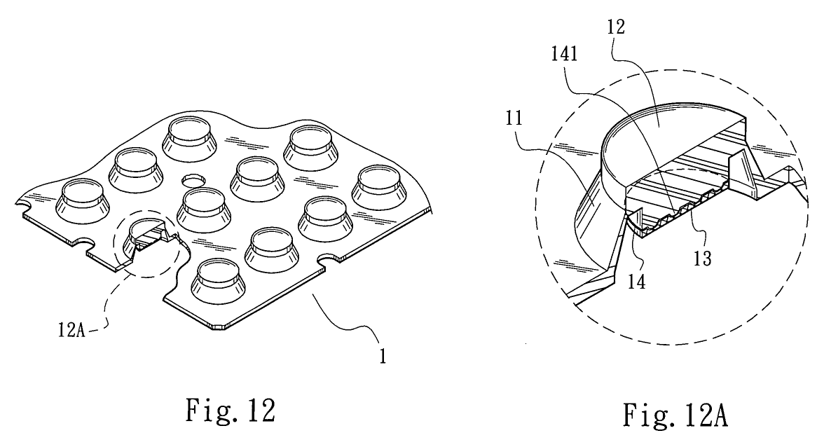

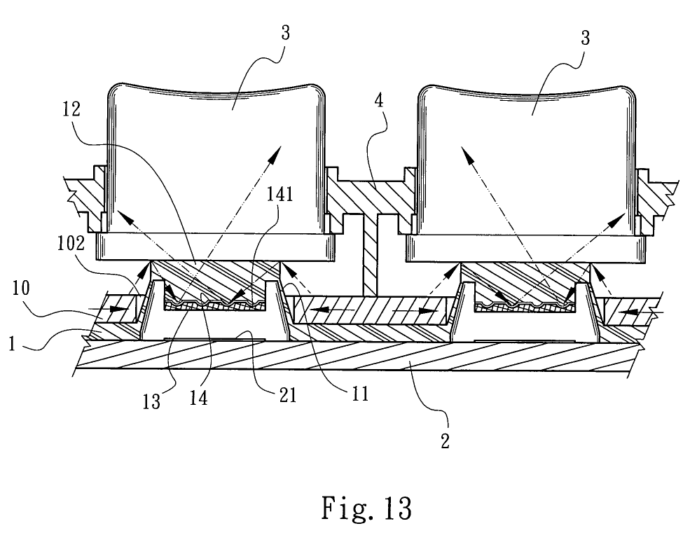

Referring to FIGS. 12, 12A and 13, the rubber sheet 1 has at least one resilient support section 11. A conductive carbon paste section 13 is disposed under the bottom face of the transparent abutment unit 12. Multiple diffusive reflection units 14 are distributed over the bottom face of the abutment unit 12 between the carbon paste section 13 and the bottom face of the abutment unit 12. In this embodiment, the diffusive reflection units 14 are boss sections, convex sections or dome sections protruding from the bottom face of the abutment unit 12 and extending into the carbon paste section 13. Alternatively, the diffusive reflection units 14 are recessed sections, concave sections or semispherical dented sections formed on the bottom face of the abutment unit 12. Each diffusive reflection unit 14 has a surface coated with a light reflection layer 141 between the diffusive reflection unit 14 and the carbon paste section 13.

Referring to FIG. 13, in practice, the rubber sheet 1 can be combined with a circuit board 2 and a light guide plate 10 to form a substrate of a backlight module. The circuit board 2 is positioned under the rubber sheet 1. Multiple electric contact points 21 are disposed on the circuit board 2 in alignment with the carbon paste sections 13. The light guide plate 10 is disposed on the upper face of the rubber sheet 1 and has an incident surface and an emission surface intersecting the incident surface. The light guide plate 10 is formed with multiple through holes 102 in alignment with the resilient support sections 11 respectively. The abutment units 12 of the resilient support sections 11 can respectively pass through the through holes 102 to abut against the bottom faces of the press keys 3. Multiple light sources are arranged on the circuit board 2 beside the incident face of the light guide plate 10.

In use, the light emitted from the light sources is incident upon the incident surface of the light guide plate 10 to pass through the light guide plate 10. The light is guided by the light guide plate 10 and most of the light is emitted from the emission surface thereof to provide backlight illumination for the press keys 3 and the transparent portions of the case 4. However, part of the backlight is reflected by the inner face of the case 4 or the lower faces of the press keys 3 back to the light guide plate 10 or the surface of the abutment unit 12. Part of the reflected light passes through the abutment unit 12 and is again reflected by the light reflection layer 141. At this time, the he diffusive reflection units 14, which are recessed sections, concave sections or semispherical dented sections, will universally reflect and uniformly scatter the light to provide uniform backlight illumination for the centers of the press keys 3 that are aligned with the abutment units 12 as shown in FIG. 13. Therefore, the shadows produced at the centers of the press keys 3 due to the carbon paste sections 13 can be avoided.

In conclusion, the diffusive reflection units of the light guide structure for the keyboard of the present invention are able to fully reflect and uniformly scatter the light to enhance utility efficiency of the light and promote backlight brightness of the press keys.

The above embodiments are only used to illustrate the present invention, not intended to limit the scope thereof. Many modifications of the above embodiments can be made without departing from the spirit of the present invention.

What is claimed is:

1. A light guide structure for a keyboard, at least comprising a transparent rubber sheet positioned between press keys of the keyboard and a circuit board, at least one raised resilient support section being disposed on the rubber sheet in alignment with a press key, a top side of the resilient support section being positioned right under a bottom face of the press key or in contact with the bottom face of the press key, diffusive reflection units being formed on a surface of the rubber sheet and distributed over a circumference of the resilient support section, each diffusive reflection unit having a surface coated with a light reflection layer.

2. The light guide structure for the keyboard as claimed in claim 1, wherein an abutment unit is disposed on the top side of the resilient support section, a top face of the abutment unit being positioned right under the bottom face of the press key or in contact with the bottom face of the press key, an electric contact section being disposed under a bottom face of the abutment unit.

3. The light guide structure for the keyboard as claimed in claim 1, wherein the diffusive reflection units are also distributed over portions of the surface of the rubber sheet that are other than the resilient support section.

4. The light guide structure for the keyboard as claimed in claim 2, wherein the diffusive reflection units are also distributed over portions of the surface of the rubber sheet that are other than the resilient support section.

5. The light guide structure for the keyboard as claimed in claim 1, wherein the resilient support section is transparent and the diffusive reflection units are distributed over inner circumference of the resilient support section.

6. The light guide structure for the keyboard as claimed in claim 2, wherein the resilient support section is transparent and the diffusive reflection units are distributed over inner circumference of the resilient support section.

7. The light guide structure for the keyboard as claimed in claim 3, wherein the resilient support section is transparent and the diffusive reflection units are distributed over inner circumference of the resilient support section.

8. The light guide structure for the keyboard as claimed in claim 1, wherein the diffusive reflection units are boss sections protruding from the surface of the rubber sheet.

9. The light guide structure for the keyboard as claimed in claim 2, wherein the diffusive reflection units are boss sections protruding from the surface of the rubber sheet.

10. The light guide structure for the keyboard as claimed in claim 3, wherein the diffusive reflection units are boss sections protruding from the surface of the rubber sheet.

11. The light guide structure for the keyboard as claimed in claim 4, wherein the diffusive reflection units are boss sections protruding from the surface of the rubber sheet.

12. The light guide structure for the keyboard as claimed in claim 8, wherein the boss sections are convex sections.

13. The light guide structure for the keyboard as claimed in claim 8, wherein the boss sections are dome sections.

14. The light guide structure for the keyboard as claimed in claim 1, wherein the diffusive reflection units are recessed sections formed on the surface of the rubber sheet.

15. The light guide structure for the keyboard as claimed in claim 2, wherein the diffusive reflection units are recessed sections formed on the surface of the rubber sheet.

16. The light guide structure for the keyboard as claimed in claim 3, wherein the diffusive reflection units are recessed sections formed on the surface of the rubber sheet.

17. The light guide structure for the keyboard as claimed in claim 5, wherein the diffusive reflection units are recessed sections formed on the surface of the rubber sheet.

18. The light guide structure for the keyboard as claimed in claim 1 wherein the diffusive reflection units are concave sections.

19. The light guide structure for the keyboard as claimed in claim 1, wherein the diffusive reflection units are semispherical dented sections.

20. The light guide structure for the keyboard as claimed in claim 1, wherein a carbon paste section is disposed under the bottom face of the abutment unit, a light reflection layer being disposed between the carbon paste section and the bottom face of the abutment unit.

21. The light guide structure for the keyboard as claimed in claim 2, wherein a carbon paste section is disposed under the bottom face of the abutment unit, a light reflection layer being disposed between the carbon paste section and the bottom face of the abutment unit.

22. The light guide structure for the keyboard as claimed in claim 3, wherein a carbon paste section is disposed under the bottom face of the abutment unit, a light reflection layer being disposed between the carbon paste section and the bottom face of the abutment unit.

23. A light guide structure for a keyboard, comprising:
at least one transparent abutment unit disposed on a rubber sheet in alignment with a press key, the abutment unit being resiliently reciprocally movable under external force;
at least one light reflection layer disposed under a bottom face of the abutment unit; and
at least one carbon paste section disposed under a bottom face of the light reflection layer, whereby the light reflection layer is able to reflect light toward the press key, which light comes from the rubber sheet or comes from an upper side thereof and passes through the abutment unit.

24. The light guide structure for the keyboard as claimed in claim 23, wherein multiple diffusive reflection units are distributed over the bottom face of the abutment unit between the light reflection layer and the bottom face of the abutment unit.

25. The light guide structure for the keyboard as claimed in claim 24, wherein the diffusive reflection units are recessed sections formed on the bottom face of the abutment unit.

26. The light guide structure for the keyboard as claimed in claim 24, wherein the diffusive reflection units are boss sections protruding from the bottom face of the abutment unit and extending into the carbon paste section.

27. The light guide structure for the keyboard as claimed in claim 23, wherein the light reflection layer is a layer of white paint.

28. The light guide structure for the keyboard as claimed in claim 24, wherein the light reflection layer is a layer of white paint.

29. The light guide structure for the keyboard as claimed in claim 23, wherein the abutment unit is disposed on a resilient support section.

30. The light guide structure for the keyboard as claimed in claim 24, wherein the abutment unit is disposed on a resilient support section.

31. The light guide structure for the keyboard as claimed in claim 27, wherein the abutment unit is disposed on a resilient support section.
